(19) United States
(12) Patent Application Publication
(10) Pub. No.: US 2023/0005931 A1
(43) Pub. Date: Jan. 5, 2023

(54) SEMICONDUCTOR STRUCTURE AND METHOD FOR MANUFACTURING SEMICONDUCTOR STRUCTURE

(71) Applicant: CHANGXIN MEMORY TECHNOLOGIES, INC., Hefei City (CN)

(72) Inventors: Junyi ZHANG, Hefei (CN); Xin LI, Hefei (CN); Zhan YING, Hefei (CN)

(21) Appl. No.: 17/516,812

(22) Filed: Nov. 2, 2021

Related U.S. Application Data
(63) Continuation of application No. PCT/CN2021/116913, filed on Sep. 7, 2021.

(30) Foreign Application Priority Data
Jul. 2, 2021 (CN) 202110753706.5

(51) Int. Cl. H01L 27/108; H01L 29/78; H01L 21/768

(52) U.S. Cl. CPC H01L 27/10885; H01L 29/7827; H01L 27/10891; H01L 21/76871

(57) ABSTRACT

The disclosure provides a semiconductor structure and a method for manufacturing a semiconductor structure, relates to the field of semiconductor manufacturing technologies. The semiconductor structure includes: a substrate, having a bit line groove; a bit line, located in the bit line groove, and extending in a first direction; and a vertical transistor, located on the bit line. The bit line includes a bit line contact structure, and the bit line contact structure is a concave structure and/or a convex structure. The vertical transistor is electrically connected to the bit line by the bit line contact structure.

### CROSS-REFERENCE TO RELATED APPLICATION

This application is a U.S. continuation application of International Application No. PCT/CN2021/116913, filed on Sep. 7, 2021, which claims priority to Chinese patent application No. 202110753706.5, filed on Jul. 2, 2021. International Application No. PCT/CN2021/116913 and Chinese patent application No. 202110753706.5 are incorporated herein by reference in their entireties.

### TECHNICAL FIELD

The disclosure relates to the field of semiconductor manufacturing technologies, and in particular, to a semiconductor structure and a method for manufacturing a semiconductor structure.

### BACKGROUND

Increases in the integration density of semiconductor devices pose higher requirements on processes for manufacturing semiconductor devices. With the evolution of technology nodes, it becomes increasingly difficult to increase a bit line contact area, and it becomes increasingly difficult to improve processes for manufacturing semiconductor memories.

### SUMMARY

According to a first aspect, the disclosure provides a semiconductor structure. The semiconductor structure includes a substrate, having a bit line groove; a bit line, located in the bit line groove, and extending in a first direction; and a vertical transistor, located on the bit line.

The bit line includes a bit line contact structure, and the bit line contact structure is a concave structure and/or a convex structure.

The vertical transistor is electrically connected to the bit line by the bit line contact structure.

According to a second aspect, the disclosure provides a method for manufacturing a semiconductor structure. The method includes the following operations.

A substrate is provided, and a bit line groove is formed in the substrate.

A bit line is formed in the bit line groove, and the bit line extends in a first direction.

A bit line contact structure is formed on the bit line, and the bit line contact structure is a concave structure and/or a convex structure.

A vertical transistor is formed on the bit line, and the vertical transistor is electrically connected to the bit line by the bit line contact structure.

The structure of the disclosure and its other application objectives and beneficial effects will become more apparent and understandable by the description of the preferred embodiments in combination with the accompanying drawings.

### BRIEF DESCRIPTION OF THE DRAWINGS

To describe the technical solutions in the embodiments of the disclosure or the prior art more clearly, the following briefly introduces the accompanying drawings required for describing the embodiments or the prior art. Apparently, the accompanying drawings in the following description show some embodiments of the disclosure, and a person of ordinary skill in the art may still derive other drawings from these accompanying drawings without creative efforts.

FIG. 1A schematically shows a structure of a first semiconductor structure according to an embodiment of the disclosure.

FIG. 1B shows a top view of the first semiconductor structure according to an embodiment of the disclosure.

FIG. 2 schematically shows a structure of a second semiconductor structure according to an embodiment of the disclosure.

FIG. 3 schematically shows a structure of a third semiconductor structure according to an embodiment of the disclosure.

FIG. 4 schematically shows a structure of a fourth semiconductor structure according to an embodiment of the disclosure.

FIG. 5 schematically shows a structure of another abutting surface of a semiconductor structure according to an embodiment of the disclosure.

FIG. 6 schematically shows a flowchart of a method for manufacturing a semiconductor structure according to an embodiment of the disclosure.

FIG. 7 schematically shows a flowchart of a method for manufacturing a bit line contact structure in a semiconductor structure according to an embodiment of the disclosure.

FIG. 8 schematically shows a flowchart of a method for manufacturing a vertical transistor in a semiconductor structure according to an embodiment of the disclosure.

FIG. 9A schematically shows a structure after a bit line groove is formed in a substrate of a first semiconductor structure according to an embodiment of the disclosure.

FIG. 9B shows a top view after a bit line groove is formed in a substrate of a first semiconductor structure according to an embodiment of the disclosure.

FIG. 10A schematically shows a structure after a bit line is formed in a bit line groove of a first semiconductor structure according to an embodiment of the disclosure.

FIG. 10B shows a top view after a bit line is formed in a bit line groove of a first semiconductor structure according to an embodiment of the disclosure.

FIG. 11A schematically shows a structure after a bit line contact structure is formed on a bit line of a first semiconductor structure according to an embodiment of the disclosure.

FIG. 11B shows a top view after a bit line contact structure is formed on a bit line of a first semiconductor structure according to an embodiment of the disclosure.

FIG. 12A schematically shows a structure after a first doped region is formed on a bit line of a first semiconductor structure according to an embodiment of the disclosure.

FIG. 12B shows a top view after a first doped region is formed on a bit line of a first semiconductor structure according to an embodiment of the disclosure.

FIG. 12C schematically shows another structure after a first doped region is formed on a bit line of a first semiconductor structure according to an embodiment of the disclosure.

FIG. 13A schematically shows a structure after a dielectric layer is formed on a substrate of a first semiconductor structure according to an embodiment of the disclosure.

FIG. 13B shows a top view after a dielectric layer is formed on a substrate of a first semiconductor structure according to an embodiment of the disclosure.

FIG. 14A schematically shows a structure after a channel region and a word line are formed in a first doped region of a first semiconductor structure according to an embodiment of the disclosure.

FIG. 14B shows a top view after a channel region and a word line are formed in a first doped region of a first semiconductor structure according to an embodiment of the disclosure.

FIG. 15A schematically shows a structure after a second doped region is formed in a channel region of a first semiconductor structure according to an embodiment of the disclosure.

FIG. 15B shows a top view after a second doped region is formed in a channel region of a first semiconductor structure according to an embodiment of the disclosure.

FIG. 16 schematically shows a structure after a bit line contact structure is formed on a bit line of a second semiconductor structure according to an embodiment of the disclosure.

FIG. 17 schematically shows a structure after a first doped region is formed on a bit line of a second semiconductor structure according to an embodiment of the disclosure.

FIG. 18 schematically shows a structure after a dielectric layer is formed on a substrate of a second semiconductor structure according to an embodiment of the disclosure.

FIG. 19 schematically shows a structure after a channel region and a word line are formed in a first doped region of a second semiconductor structure according to an embodiment of the disclosure.

FIG. 20 schematically shows a structure after a second doped region is formed in a channel region of a third semiconductor structure according to an embodiment of the disclosure.

FIG. 21 schematically shows a structure after a bit line contact structure is formed on a bit line of a third semiconductor structure according to an embodiment of the disclosure.

FIG. 22 schematically shows a structure after a first doped region is formed on a bit line of a third semiconductor structure according to an embodiment of the disclosure.

FIG. 23 schematically shows a structure after a dielectric layer is formed on a substrate of a third semiconductor structure according to an embodiment of the disclosure.

FIG. 24 schematically shows a structure after a channel region and a word line are formed in a first doped region of a third semiconductor structure according to an embodiment of the disclosure.

FIG. 25 schematically shows a structure after a second doped region is formed in a channel region of a third semiconductor structure according to an embodiment of the disclosure.

### DETAILED DESCRIPTION

As discussed in the BACKGROUND, in a current semiconductor structure, in one aspect, because a contact surface between a bit line and a transistor is planar, a contact area is relatively small, and in another aspect, because a feature size of a MOS transistor is reduced, the contact area between the bit line and the transistor is further reduced. As a result, a contact resistance between the bit line and the transistor is increased, leading to the decrease of signal transmission performance and the decrease of semiconductor structure performance.

In view of this, the disclosure provides a bit line contact structure with a concave structure and/or a convex structure, so that when a vertical transistor is electrically connected to a bit line by the bit line contact structure, a contact area of the bit line contact structure can be effectively increased, a contact resistance at the bit line contact structure can be reduced, and a charge transmission speed can be increased, thereby improving a signal transmission speed. In addition, in the semiconductor structure provided in the disclosure and a method for manufacturing a semiconductor structure, by forming a bit line groove in a substrate, the bit line can be arranged in the bit line groove to facilitate the formation of a buried bit line structure, which helps to improve the stability of the semiconductor structure. Meanwhile, compared with a planar transistor, the vertical transistor in the disclosure can effectively improve the level of integration of devices and increase a storage capacity while occupying the same area on the substrate.

In order to make the objectives, technical solutions, and advantages of the disclosure clearer, the technical solutions in the embodiments of the disclosure are described in detail hereinafter with reference to the accompanying drawings of the preferred embodiments of the disclosure. In the accompanying drawings, the same or similar numerals represent the same or similar parts or parts having the same or similar functions throughout the specification. The described embodiments are merely some rather than all of the embodiments of the disclosure. The embodiments described below with reference to the accompanying drawings are exemplary, and are used to explain the disclosure but should not be construed as a limitation to the disclosure. All other embodiments obtained by persons of ordinary skill in the art based on the embodiments of the disclosure without creative efforts fall within the protection scope of the disclosure. The embodiments of the disclosure are described below in detail with reference to the accompanying drawings.

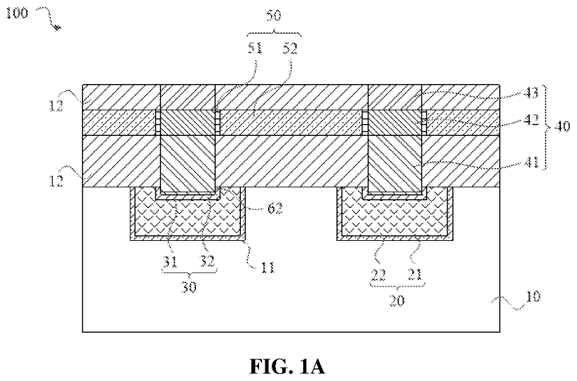

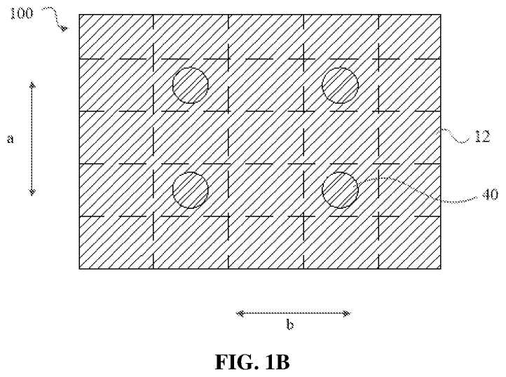

According to the first aspect, the embodiments of the disclosure provide a semiconductor structure. As shown in FIG. 1A and FIG. 1B, the semiconductor structure 100 includes: a substrate 10, having a bit line groove 11; a bit line 20, located in the bit line groove 11, and extending in a first direction; a vertical transistor 40, located on the bit line 20. The bit line 20 includes a bit line contact structure 30, and the bit line contact structure 30 is a concave structure and/or a convex structure. The vertical transistor 40 is electrically connected to the bit line 20 by the bit line contact structure 30. Through the arrangement of the bit line contact structure 30, the vertical transistor 40 is electrically connected to the bit line 20 by the bit line contact structure 30. Through setting the bit line contact structure 30 as the concave structure and/or the convex structure, the contact area between the vertical transistor 40 and the bit line 20 can be increased, the contact resistance between the bit line 20 and the vertical transistor 40 can be reduced, and the charge transmission speed can be increased, thereby increasing a signal transmission speed and improving the use stability of the semiconductor structure 100.

It should be noted that, “a concave structure and/or a convex structure” herein means that the overall structure of the bit line contact structure 30 is the concave structure, the convex structure, or a combination of the concave structure and the convex structure. The bit line contact structure 30 provided in the embodiments of the disclosure has a larger contact area than a planar contact structure in the related art.

It should be noted that, by forming the bit line groove 11 in the substrate 10, the bit line 20 can be arranged in the bit line groove 11, to facilitate the formation of a buried bit line structure. By setting the vertical transistor 40, while the same area on the substrate 10 is occupied, the level of integration of the semiconductor structure 100 can be effectively improved, and a storage capacity can be increased, compared with a planar transistor.

It should be noted that, in FIG. 1B, a direction a denotes the first direction, and a direction b denotes the second direction. The material of the substrate 10 may be monocrystalline silicon, polycrystalline silicon, amorphous silicon, a silicon-germanium compound, silicon-on-insulator (abbreviated as SOI) or the like, or other materials known to a person skilled in the art. The substrate 10 may provide a support basis for a structural layer on the substrate 10. The semiconductor structure 100 may be a storage device or a non-storage device. The storage device may include, for example, a Dynamic Random Access Memory (DRAM), a Static Random Access Memory (SRAM), a flash memory, an Electrically Erasable Programmable Read-Only Memory (EEPROM), a Phase Change Random Access Memory (PRAM) or a Magnetoresistive Random Access Memory (MRAM). The non-storage device may be a logic device (for example, a microprocessor, a digital signal processor, or a microcontroller) or similar devices thereof.

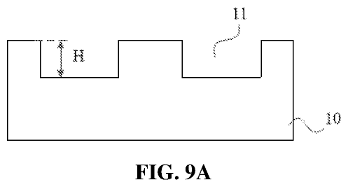

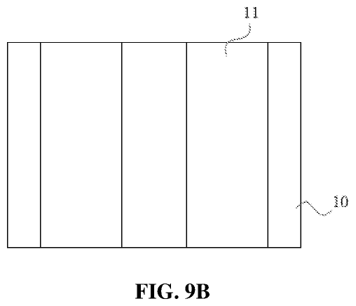

It should be noted that, as shown in FIG. 9A, the bit line groove 11 has a height ranging from 50 nm to 200 nm. In this figure, H denotes this height. The height may be specifically 50 nm, 100 nm, 150 nm, 180 nm, or 200 nm. The bit line groove 11 with the height within the above range, can in one aspect reduce the vertical height of the semiconductor structure 100, and in another aspect, enables both the bit line 20 and the vertical transistor 40 to be firmly connected to the substrate 10, thereby improving the stability of the semiconductor structure 100.

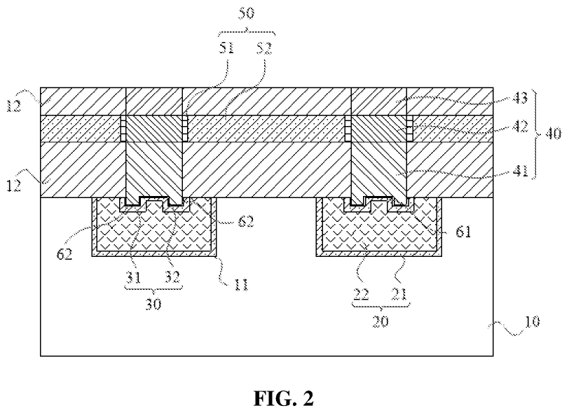

Specifically, as shown in FIG. 2, the bit line 20 includes a first conductive layer 21 and a second conductive layer 22. The first conductive layer 21 is located on an inner wall surface of the bit line groove 11. The second conductive layer 22 is located on the first conductive layer 21. The second conductive layer 22 may be made by a material with a relatively low resistance such as W, TiN, TaN, Al, Ru or Cu. The material of the first conductive layer 21 may include TiN. In one aspect, TiN has a certain barrier effect and can effectively prevent the metal material of the second conductive layer 22 from diffusing to the substrate. In another aspect, TiN has good interface compatibility with the metal material, which can effectively reduce structural defects at interfaces and improve the yield of semiconductor structures.

Specifically, the bit line contact structure 30 includes a transition layer 31 and a seed layer 32. The seed layer 32 is located on a side of the transition layer 31 away from the substrate 10. The transition layer 31 may be a TiN layer. TiN has good interface compatibility with the metal material of the second conductive layer 22, which can effectively reduce structural defects at interfaces. The seed layer 32 may be made by polycrystalline silicon. Polycrystalline silicon can be converted into monocrystalline silicon by using an annealing process, so that the vertical transistor 40 is epitaxially grown based on monocrystalline silicon.

Specifically, the vertical transistor 40 is located on the bit line contact structure 30, and embedded with the bit line contact structure 30. In this way, in one aspect, a contact resistance at the bit line contact structure 30 can be reduced, and in another aspect, because the vertical transistor 40 has relatively higher vertical height, the vertical transistor 40 and the bit line contact structure 30 can be connected in an embedded manner, which is beneficial to improve the structural stability of the semiconductor structure 100.

Specifically, the vertical transistor 40 includes a first doped region 41, a channel region 42, and a second doped region 43 that are sequentially stacked. The first doped region 41 contacts the bit line 20. The same type of doped ions is used in the first doped region 41, the channel region 42, and the second doped region 43. For example, the doped ions may be N-type ions or P-type ions.

The vertical transistor 40 further includes a capacitor (not shown). The second doped region 43 of the vertical transistor 40 is electrically connected to the capacitor. In the embodiments of the disclosure, the first doped region constitutes one of a source and a drain of the vertical transistor, and the second doped region constitutes the other of the source and the drain of the vertical transistor. In this way, when a voltage is applied between the first doped region and the second doped region, a current may flow through the channel region 42, and the first doped region is electrically connected to the bit line 20, so that a current path can be formed.

Specifically, the semiconductor structure 100 further includes a word line 50 and an isolation structure. The word line 50 is arranged surrounding the channel region 42, and extends in the second direction. In this way, a plurality of channel regions may be electrically connected in the second direction by the word line 50. The isolation structure is located between adjacent bit lines 20, and can prevent short circuit between the adjacent bit lines 20, thereby avoiding the effect on the stability of the semiconductor structure 100. In the embodiments of the disclosure, the substrate 10 between the adjacent bit lines 20 constitutes the isolation structure.

Specifically, the word line 50 includes a gate dielectric layer 51 and a gate conductive layer 52. The gate dielectric layer 51 is arranged surrounding the channel region 42. The gate conductive layer 52 is arranged surrounding the channel region 42, and is located on a side surface of the gate dielectric layer 51 corresponding to the channel region 42. The gate dielectric layer 51 and the gate conductive layer 52 together constitute the word line 50. Each word line 50 may surround at least one channel region 42. The material of the gate dielectric layer 51 may be an oxide, for example, silicon oxide. The material of the gate conductive layer 52 may be metal or a metal compound such as W, TiN, TaN, Al, Ru or Cu.

Specifically, the bit line contact structure 30 includes three structures. The first structure includes one concave structure. The second structure includes one convex structure. The third structure includes at least one concave structure and at least one convex structure.

In some embodiments, as shown in FIG. 1A, the bit line contact structure 30 includes one concave structure 62. The concave structure 62 may be directly formed through etching, which simplifies the manufacturing process while increasing the contact area of the bit line.

In other embodiments, as shown in FIG. 2, the bit line contact structure 30 includes two concave structures 62 and one convex structure 61. The convex structure 61 is arranged between the two concave structures 62, thereby further increasing the bit line contact area, reducing the bit line contact resistance, and increasing the charge transmission speed.

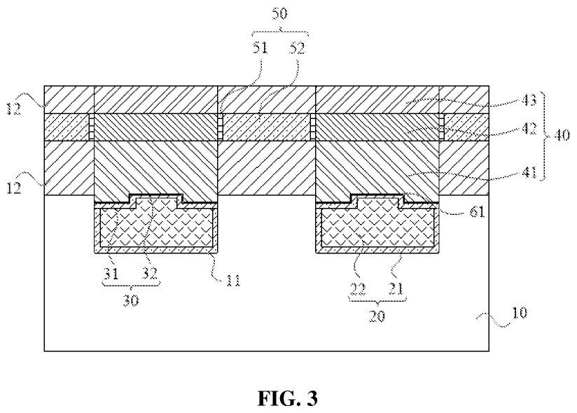

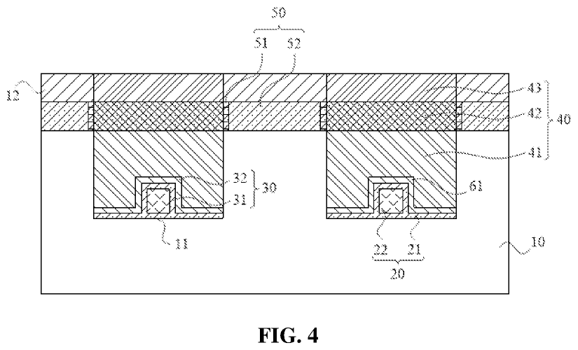

In some embodiments, as shown in FIG. 3 and FIG. 4, the bit line contact structure may further include one convex structure 61. It should be noted that, compared with the structure in FIG. 3, the height of the bit line groove shown in FIG. 4 is further reduced, so that while the bit line contact area is increased, the height of the semiconductor structure is also reduced, thereby improving the stability of the semiconductor structure.

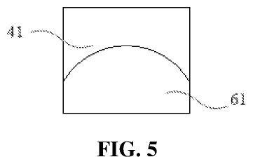

In the embodiments of the disclosure, as shown in FIG. 5, the surface of the bit line contact structure 30 may be a curved surface, which can avoid a right-angle structure in the bit line contact structure 30, causing the bit line contact structure 30 more smooth, and thus reducing the bit line contact resistance.

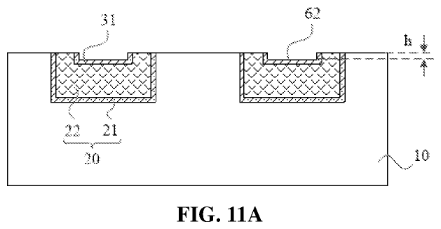

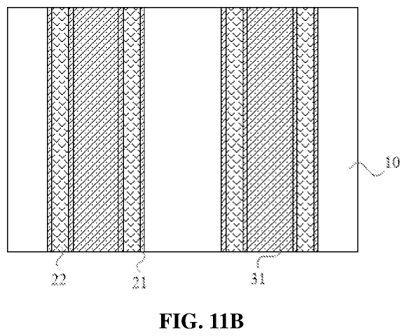

It should be noted that, the convex structure and/or the concave structure of the bit line contact structure 30 may have the same height. In the embodiments of the disclosure, the concave structure 62 is taken as an example for description. As shown in FIG. 11A, the convex structure, and/or the concave structure may have the height ranging from 1 nm to 10 nm. In this figure, h denotes the height. Specifically, the height may be 1 nm, 3 nm, 4 nm, 6 nm, 7 nm, 9 nm or 10 nm. When the convex structure and/or the concave structure has the height within the above range, it is ensured that the bit line contact area is increased, improving the structural stability of the vertical transistor.

The embodiments of the disclosure further provide a method for manufacturing a semiconductor structure. The method for manufacturing a semiconductor structure may be used to manufacture the above semiconductor structure.

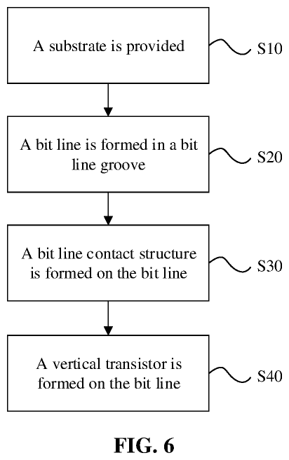

As shown in FIG. 6, the method for manufacturing a semiconductor structure includes the following operations.

At S10, a substrate is provided. As shown in FIG. 9A and FIG. 9B, a bit line groove 11 is formed in the substrate 10 by etching.

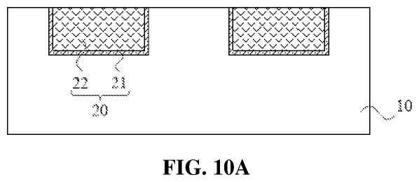

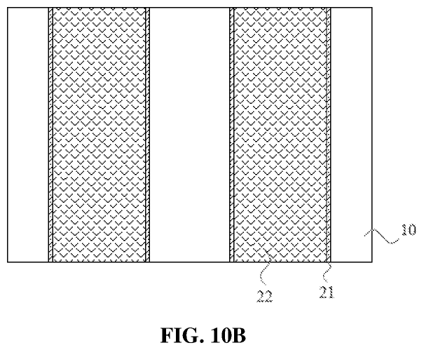

At S20, a bit line is formed in the bit line groove. As shown in FIG. 10A and FIG. 10B, the bit line 20 is formed by sequentially depositing a first conductive layer 21 and a second conductive layer 22 in the bit line groove 11. The bit line 20 extends in a first direction.

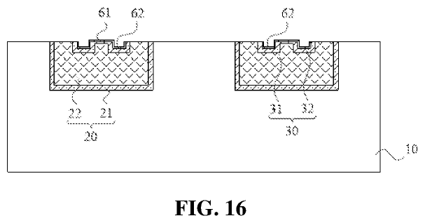

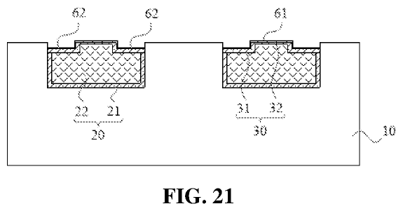

At S30, a bit line contact structure is formed on the bit line. The bit line contact structure 30 is a concave structure and/or a convex structure. As shown in FIG. 11A and FIG. 11B, a bit line contact structure 30 of a first semiconductor structure 100 is a concave structure 62. As shown in FIG. 16, a bit line contact structure 30 of a second semiconductor structure 100 includes two concave structures 62 and one convex structure 61. As shown in FIG. 21, a bit line contact structure 30 of a third semiconductor structure 100 includes one convex structure 61.

At S40, a vertical transistor is formed on the bit line. The vertical transistor 40 is electrically connected to the bit line 20 by the bit line contact structure 30. Specifically, the vertical transistor 40 is formed on the bit line contact structure 30, and the vertical transistor 40 is embedded with the bit line contact structure 30.

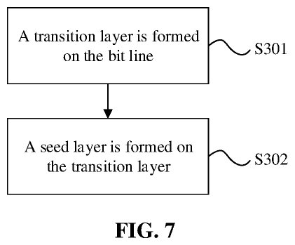

Specifically, as shown in FIG. 7, the formation of the bit line contact structure on the bit line includes the following operations.

At S301, a transition layer is formed on the bit line. The material of a transition layer 31 includes TiN, W, TaN, Al, Ru, Cu or the like.

At S302, a seed layer is formed on the transition layer. The material of a seed layer 32 includes polycrystalline silicon, which facilitates the epitaxial growth of other structural layers.

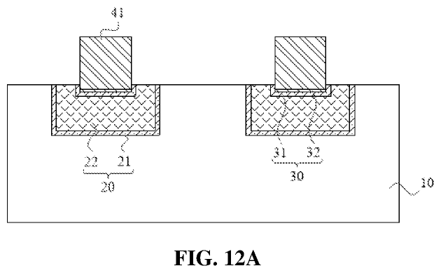

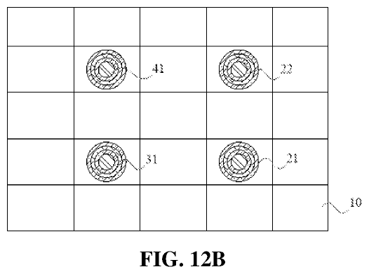

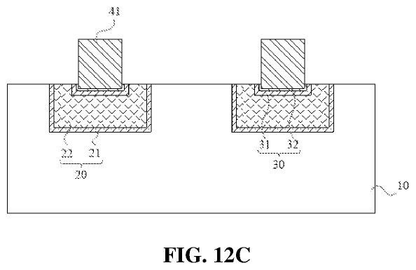

It should be noted that, the seed layer 32 is formed in the following two manners. In the first manner, as shown in FIG. 12A and FIG. 12B, the seed layer 32 is only formed on a bottom wall of the transition layer 31. In the second manner, as shown in FIG. 12C, the seed layer 32 is formed on a bottom wall and a side wall of the transition layer 31. A manner of forming the seed layer is not limited in the embodiments of the disclosure.

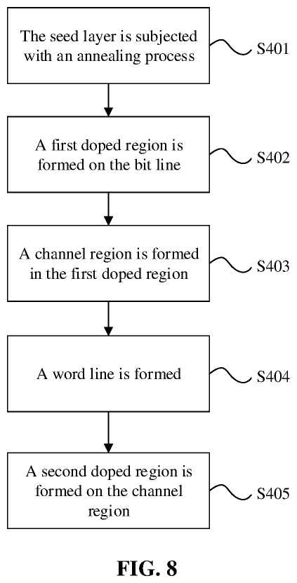

It should be noted that, in the embodiments of the disclosure, the vertical transistor 40 is formed on the seed layer 32. Specifically, as shown in FIG. 8, a method for manufacturing the vertical transistor includes the following operations.

At S401, the seed layer is subjected with an annealing process. The annealing process is performed under a temperature of 500° C. to 1,000° C. for the total time of 3 h to 5 h. Specifically, the annealing process may be performed under a high temperature of 850° C. for 30 minutes, and under a high temperature of 550° C. for 4 hours. The two operations are sequentially performed, to reduce structural defects after polycrystalline silicon is converted into monocrystalline silicon, thereby improving the quality of the vertical transistor obtained by subsequent epitaxial growth.

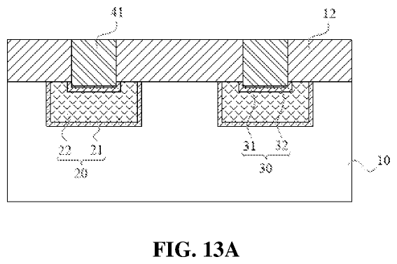

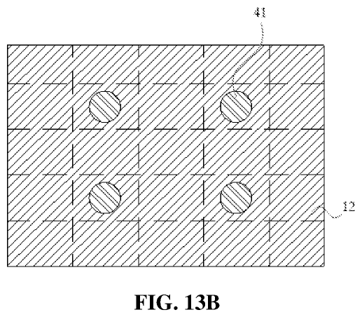

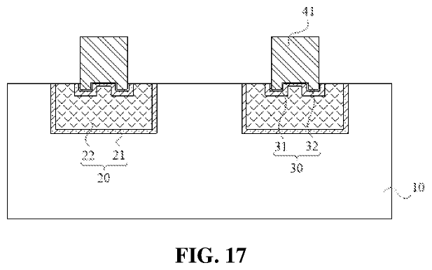

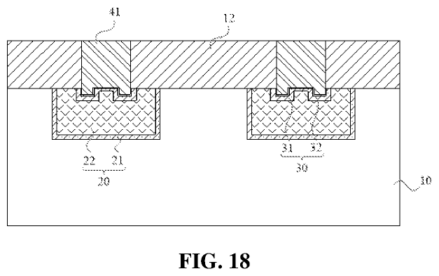

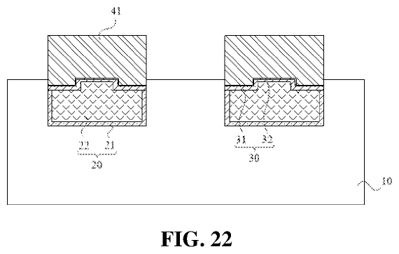

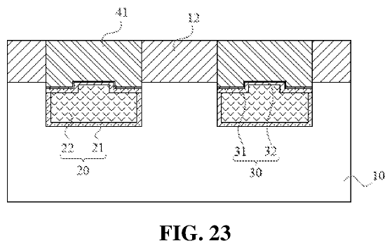

At S402, a first doped region is formed on the bit line. The structure of the second semiconductor structure 100 after the first doped region 41 is formed is shown in FIG. 17. The structure of the third semiconductor structure 100 after the first doped region 41 is formed is shown in FIG. 22. Specifically, after the first doped region 41 is formed, a dielectric layer 12 is formed on the substrate 10. An upper surface of the dielectric layer 12 is flush with an upper surface of the first doped region 41. The structure after the dielectric layer 12 is formed on the substrate 10 of the first semiconductor structure 100 is shown in FIG. 13A and FIG. 13B. The structure after the dielectric layer 12 is formed on the substrate 10 of the second semiconductor structure 100 is shown in FIG. 18. The structure after the dielectric layer 12 is formed on the substrate 10 of the third semiconductor structure 100 is shown in FIG. 23. The dielectric layer 12 may be an oxide layer.

At S403, a channel region is formed in the first doped region.

At S404, a word line is formed. The word line 50 is arranged surrounding the channel region 42, and extends in a second direction. First, a gate dielectric layer 51 is formed. The gate dielectric layer 51 is arranged surrounding the channel region 42. Next, a gate conductive layer 52 is arranged on the periphery of the gate dielectric layer 51. The gate conductive layer 52 is arranged surrounding the channel region 42, and is located on a side surface of the gate dielectric layer 51. The gate dielectric layer 51 and the gate conductive layer 52 together constitute the word line 50. Each word line 50 may surround at least one channel region 42.

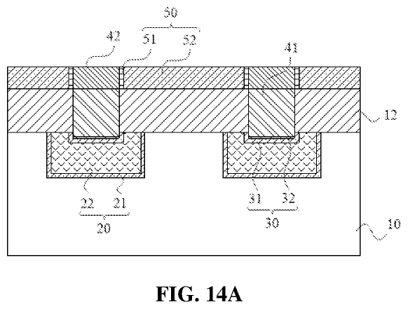

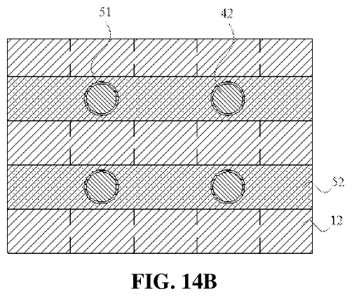

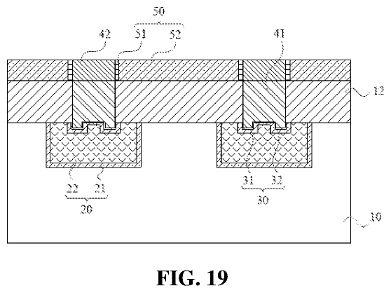

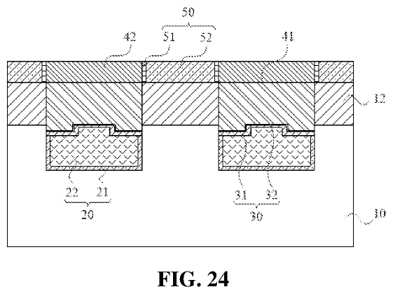

It should be noted that, the structure of the first semiconductor structure 100 after the word line 50 is formed is shown in FIG. 14A and FIG. 14B. The structure of the second semiconductor structure 100 after the word line 50 is formed is shown in FIG. 19. The structure of the third semiconductor structure 100 after the word line 50 is formed is shown in FIG. 24.

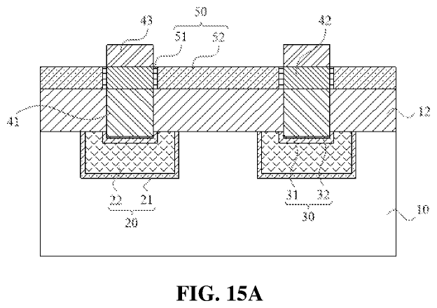

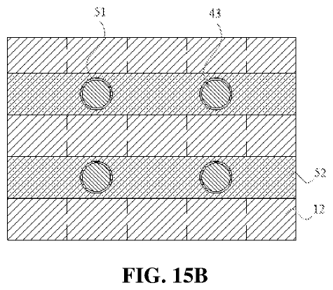

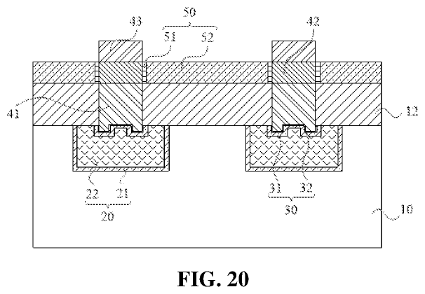

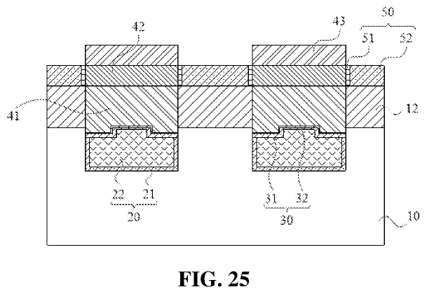

At S405, a second doped region is formed in the channel region. The structure of the first semiconductor structure 100 after the second doped region 43 is formed is shown in FIG. 15A and FIG. 15B. The structure of the third semiconductor structure 100 after the second doped region 43 is formed is shown in FIG. 20. The structure of the third semiconductor structure 100 after the word line 50 is formed is shown in FIG. 25. Doped ions in the first doped region 41, the channel region 42, and the second doped region 43 are of the same type. For example, the doped ions are all N-type ions or are all P-type ions. After the second doped region 43 is formed, the dielectric layer 12 may be further arranged on the word line 50, so that the word line 50 can be prevented from contacting other structures.

In the method for manufacturing the semiconductor structure 100 according to an embodiment of the disclosure, by forming the bit line contact structure 30 with the concave structure and/or the convex structure on the bit line 20, the contact area of the bit line contact structure 30 is effectively increased when the vertical transistor 40 is electrically connected to the bit line 20 by the bit line contact structure 30, the bit line contact resistance is reduced, and the charge transmission speed is increased, thereby increasing a signal transmission speed. By forming the bit line 20 in the bit line groove 11, it is beneficial to the formation of a buried bit line structure. In addition, compared with a planar transistor, the vertical transistor 40 in the disclosure can effectively improve the level of integration of devices and increase a storage capacity, while occupying the same area on the substrate.

In the description, it should be noted that unless otherwise expressly specified and defined, terms “mounted”, “connected”, and “connection” should be understood in a broad sense, for example, two elements are fixedly connected, or are connected through an intermediate, or are communicated internally, or are interacting with each other. For persons skilled in the art, specific meanings of the terms in the disclosure should be understood according to specific conditions. Orientation or location relationships indicated by terms “up”, “down”, “front”, “rear”, “vertical”, “horizontal”, “top”, “bottom”, “inside”, and “outside” are based on orientation or location relationships shown in the accompanying drawings, and are only used to facilitate description of the disclosure and simplify description, but are not used to indicate or imply that the apparatuses or elements must have specific orientations or are constructed and operated by using specific orientations, and therefore, cannot be understood as a limitation to the disclosure. In the description of the disclosure, “a plurality of” herein means “two or more” unless otherwise precisely and specifically described.

The terms such as “first”, “second”, “third”, “fourth” (if exist) in the specification, claims, and the accompanying drawings of the disclosure are only used to distinguish among similar objects, but are not used to describe a specific order or time sequence. It should be understood that the data thus used are interchangeable in appropriate circumstances and that the embodiments of the disclosure described herein, for example, can be implemented in other sequences than those illustrated or described. In addition, the terms “include”, “comprise”, and any variation of such terms in the description and claims of the disclosure are intended to cover a non-exclusive inclusion. For example, a process, method, system, product or device that includes a series of steps or units not only includes those steps or units specified expressly, but also includes other steps or units that are not specified expressly or are inherent to the process, method, product or device.

Finally, it should be noted that the foregoing embodiments are merely intended for describing the technical solutions of the disclosure rather than limiting the disclosure. Although the disclosure is described in detail with reference to the foregoing embodiments, persons of ordinary skill in the art should understand that they may still make modifications to the technical solutions described in the foregoing embodiments or make equivalent replacements to some or all the technical features thereof, without departing from the scope of the technical solutions of the embodiments of the disclosure.

1. A semiconductor structure, comprising:
a substrate, having a bit line groove;
a bit line, located in the bit line groove, and extending in a first direction; and
a vertical transistor, located on the bit line;
wherein the bit line comprises a bit line contact structure, and the bit line contact structure is a concave structure and/or a convex structure; and
the vertical transistor is electrically connected to the bit line by the bit line contact structure.

2. The semiconductor structure according to claim 1, wherein the vertical transistor is located on and embedded with the bit line contact structure.

3. The semiconductor structure according to claim 2, wherein the bit line contact structure comprises a transition layer and a seed layer, and the seed layer is located on an upper surface of the transition layer.

4. The semiconductor structure according to claim 1, wherein the vertical transistor comprises a first doped region, a channel region, and a second doped region that are sequentially stacked, and the first doped region is contacted with the bit line.

5. The semiconductor structure according to claim 4, wherein the semiconductor structure further comprises:
a word line, arranged surrounding the channel region, and extending in a second direction; and
an isolation structure, located between adjacent bit lines.

6. The semiconductor structure according to claim 5, wherein the word line comprises:
a gate dielectric layer, arranged surrounding the channel region; and
a gate conductive layer, arranged surrounding the channel region, and located on a side surface of the gate dielectric layer corresponding to the channel region.

7. The semiconductor structure according to claim 1, wherein the bit line contact structure comprises at least one concave structure and/or at least one convex structure.

8. The semiconductor structure according to claim 1, wherein a surface of the bit line contact structure is a curved surface or a folded surface.

9. The semiconductor structure according to claim 8, wherein the bit line groove has a height of 50 nm to 200 nm.

10. The semiconductor structure according to claim 9, wherein the convex structure and/or the concave structure has a height of 1 nm to 10 nm.

11. A method for manufacturing a semiconductor structure, comprising:
providing a substrate, and forming a bit line groove in the substrate;
forming a bit line in the bit line groove, the bit line extending in a first direction;
forming a bit line contact structure on the bit line, the bit line contact structure being a concave structure and/or a convex structure; and
forming a vertical transistor on the bit line, the vertical transistor being electrically connected to the bit line by the bit line contact structure.

12. The method for manufacturing a semiconductor structure according to claim 11, wherein the formation of the vertical transistor on the bit line comprises:
forming the vertical transistor on the bit line contact structure, the vertical transistor being embedded with the bit line contact structure.

13. The method for manufacturing a semiconductor structure according to claim 12, wherein the formation of the bit line contact structure on the bit line comprises:
forming a transition layer on the bit line, a material of the transition layer comprising TiN; and
forming a seed layer on the transition layer, a material of the seed layer comprising polycrystalline silicon.

14. The method for manufacturing a semiconductor structure according to claim 13, wherein the formation of the vertical transistor on the bit line contact structure comprises:
forming the vertical transistor on the seed layer.

15. The method for manufacturing a semiconductor structure according to claim 14, further comprising, subjecting the seed layer with an annealing process, before the formation of the vertical transistor on the seed layer.

16. The method for manufacturing a semiconductor structure according to claim 15, wherein the formation of the vertical transistor on the bit line comprises:
forming a first doped region on the bit line;
forming a channel region in the first doped region;
forming a word line, arranged surrounding the channel region, and extending in a second direction; and
forming a second doped region in the channel region.

17. The method for manufacturing a semiconductor structure according to claim 16, wherein the formation of the word line comprises:
forming a gate dielectric layer, the gate dielectric layer being arranged surrounding the channel region; and
forming a gate conductive layer on a periphery of the gate dielectric layer, the gate conductive layer being arranged surrounding the channel region, and being located on a side surface of the gate dielectric layer corresponding to the channel region.
